(19) United States
(12) Patent Application Publication
(10) Pub. No.: US 2008/0271778 A1
(43) Pub. Date: Nov. 6, 2008

(54) USE OF ELECTROMAGNETIC EXCITATION OR LIGHT-MATTER INTERACTIONS TO GENERATE OR EXCHANGE THERMAL, KINETIC, ELECTRONIC OR PHOTONIC ENERGY

(76) Inventors: Anthony Defries, Los Angeles, CA (US); Mark Brongersma, Redwood City, CA (US)

Correspondence Address: MATTER, INC., 149 S. BARRINGTON AVE #757, LOS ANGELES, CA, 90049, US

(21) Appl. No.: 11/923,584

(22) Filed: Oct. 24, 2007

Related U.S. Application Data
(60) Provisional application No. 60/866,169, filed on Nov. 16, 2006.

(51) Int. Cl. H01L 31/04; G11C 11/21; H01L 31/00

(52) U.S. Cl. 136/252; 365/129; 257/431; 290/1 R; 977/933; 977/939

(57) ABSTRACT

The present disclosure concerns a means to use at least a form of electromagnetic excitation or light-matter interactions in a structure or material having one or more addressable frequencies to generate the exchange of thermal, kinetic, electronic or photonic energy. In some implementations this provides a means to use electromagnetic excitation or light-matter interactions to influence, cause, control, modulate, stimulate or change the state or phase of electrical, magnetic, optical or electromagnetic charge, emission, conduction, storage or similar properties. The method could include the use of light-matter interactions to generate electromagnetic excitation or light-matter interactions and concentrate extremely localized field effects or concentrated plasmonic field effects to cause an exchange of energy states in a material or structure. Said field effects could be used for excitation of surface electrons in metallic nanostructures causing said electrons to exchange energy states or said field effects could be used to mediate or stimulate photon emissions or to modulate photonic energy to excite or stimulate emissions of electrons. Said electron or photon emissions could be used to drive photochemical, photocatalysis, photovoltaic or thermophotovoltaic reactions.

### CROSS REFERENCE TO RELATED APPLICATIONS

This application claims benefit of and priority to U.S. Provisional Patent Application No. 60/866,169 filed Nov. 16, 2006 entitled “Use of electromagnetic excitation or light-matter interactions to generate the exchange or thermal, kinetic, electronic or photonic energy.”

### STATEMENT AS TO RIGHTS TO INVENTIONS MADE UNDER FEDERALLY SPONSORED RESEARCH AND DEVELOPMENT

NOT APPLICABLE

### BACKGROUND

1. Field

The present disclosure concerns a means to use at least a form of electromagnetic excitation or light-matter interactions in a structure or material having one or more addressable frequencies to generate the exchange of thermal, kinetic, electronic or photonic energy. In some implementations this provides a means to use electromagnetic excitation or light-matter interactions to influence, cause, control, modulate, stimulate or change the state or phase of electrical, magnetic, optical or electromagnetic charge, emission, conduction, storage or similar properties. The method could include the use of light-matter interactions to generate electromagnetic excitation or light-matter interactions and concentrate extremely localized field effects or concentrated plasmonic field effects to cause an exchange of energy states in a material or structure. Said field effects could be used for excitation of surface electrons in metallic nanostructures causing said electrons to exchange energy states or said field effects could be used to mediate or stimulate photon emissions or modulate photonic energy to excite or stimulate emissions of electrons. Said electron or photon emissions could be used to drive photochemical, photocatalysis, photovoltaic or thermophotovoltaic reactions. Said exchange of energy states could be made to perform the functions of a solar cell, capacitor, battery, transistor, resistor, semiconductor, and information or signal storage, exchange, inversion or restoration. Spatial and temporal control may be obtained by restricting and directing the electromagnetic excitation or light-matter interactions to specific objects or features embedded or located in or on a host, matrix, material, coating or substrate. The method of use could include control of light-matter interactions addressed at optical or other frequencies to generate controlled localized thermal conditions. A further implementation concerns a means to employ electromagnetic excitation or light-matter interactions to generate localized thermal conditions to control or cause the combination, separation, reformation or reclamation of a gas, a combination of gasses, a material or a combination of materials in the form of a gas, plasma, solid or liquid. The method of use disclosed could provide a means to control chemical reactions for the generation, use, transfer and output of controlled localized thermal heat or energy. The method of use disclosed could provide a means to realize and control local thermal conditions down to or below the length scale of a single nanometer and down to or below the timescale of a single picosecond. In some implementations surface plasmon excitations may be used to realize and control local thermal conditions down to or below the length scale of a single nanometer and down to or below the timescale of a single picosecond.

2. Related Art

Nanofabrication techniques have enabled the generation of features that can be addressed to manipulate light at the nanoscale. Nanoscale objects or apertures at the nanoscale allow electromagnetic energy to be addressed, concentrated or restricted to critical dimensions that are below the diffraction limit of the wavelength of irradiation used. These concentrated fields can be used by means of absorption to efficiently heat volumes of material down to or below the scale of a single nanometer. Due to the small heat capacity that volume of material would cool rapidly when the electromagnetic excitation or light-matter interactions is terminated. Depending on the thermal environment of the heated volume cooling could take place on a timescale down to or below a single picosecond. The concentration could lead to massive field enhancements resulting in extreme control of light-matter interactions and local heating. An example of strong light-matter interactions can be found in metallic nanostructures. These interactions between electromagnetic excitations and metallic nanoparticles are studied in the field of plasmonics. In some implementations this provides a means to use electromagnetic excitation or light-matter interactions to influence, cause, control, modulate, stimulate or change the state or phase of electrical, magnetic, optical or electromagnetic charge, emission, conduction, storage or similar properties. The method could include the use of light-matter interactions to generate electromagnetic excitation or light-matter interactions and concentrate extremely localized field effects or concentrated plasmonic field effects to cause an exchange of energy states in a material or structure. Said field effects could be used for excitation of surface electrons in metallic nanostructures causing said electrons to exchange energy states or said field effects could be used to mediate or stimulate photon emissions or modulate photonic energy to excite or stimulate emissions of electrons.

The surface plasmon resonance effect resulting from a strong interaction between light and nanostructured metals allows for development of a new generation of photonic devices and processing technologies. The surface plasmon resonance effect is identified and may be addressed by the absorption of electromagnetic energy at or near the surface plasmon resonance frequency. This phenomenon may be exploited to open new kinetic pathways for chemical synthesis and reactions that are thermodynamically unfavorable under current processing conditions. Reactions in which metallic nanoparticles provide the catalytic sites are excellent candidates for exploiting surface plasmon excitations. Synthesis routes or chemical reactions that benefit from local heating by surface plasmons are termed plasmon enhanced. Chemical reactions can also be plasmon enhanced through the ability to locally control temperatures and enable rapid heating and cooling. This allows for rapid switching between low and high temperature states of the catalyst particles. At low temperatures reactions proceed slowly, generating high molecular sticking probabilities. At high temperatures reactions proceed quickly and rapid desorption of reactants from the particles is ensured. Rapidly cycling the temperature of the particles would permit the thermodynamics of a reaction to be exploited at preferred processing temperatures.

Generating local heat through the use of plasmon excitations allows reactions to be stimulated in a low temperature environment. In some cases quantum effects associated with metal nanoparticles can be addressed to cause further unique behavior and increase reactivity of such particles. This invention concerns the ability to concentrate significant amounts of electromagnetic energy into nanoscale volumes and convert that electromagnetic energy into the excitation of electrons, phonons, polaritons, or lattice vibrations, i.e. heat. Local heat generation will give rise to a local temperature increase in proximity to the heated volume of material without heating the entirety of the reactor mass or surrounding environment. In some instances high temperatures may occur in a restricted area while heating a volume many times larger. The concomitant local temperature increase in the heated volume will facilitate new chemical and physical synthesis processes with improved performance by many orders of magnitude in both the degree of spatial and temporal control and energy efficiency.

In an exemplary embodiment the invention described herein may be used for the initiation and control of chemical reactions, catalytic chemical reactions and chemical synthesis including FT and other exothermic reactions. The method or process described by this invention may be incorporated or expressed in a plurality of forms including nanoparticles in the form of powder, pellets, liquid, suspension, gas, plasma or otherwise, carbon nanotubes or rods, nanowires, nanostructures, nanoreactors, microstructures, microreactors, macrostructures or other devices.

An exemplary method of the embodiment previously described may include the process whereby light matter interactions are used to control and direct the deposition or fabrication of devices or structures, which incorporate nanoscale architecture and nanoparticle metallic catalysts expressed in a plurality of forms including powder, pellets, liquid, suspension, gas, plasma or otherwise, carbon nanotubes or rods, nanowires, nanostructures, nanoreactors, microstructures, microreactors, macrostructures, zeolites or other devices. Use of said devices or structures may include a method or means to incorporate the process in exothermic, chemical reactions and chemical catalysis, e.g. FT or FT synthesis reactions and endothermic reactions such as Haber-Bosch (HB). The method may further include using plasmon resonant frequencies to address the structure or device so as to modulate the thermal index of chemical reactions by rapidly changing the heat index of specific locations or areas in such a manner as to cause the structure addressed to act as a heat exchanger or a component in a heat exchanger.

An exemplary embodiment of the invention described herein may include the ability to extend the effects of local heating to adjacent particles, materials or structures. Electromagnetic excitation or light-matter interactions of specific objects or features may be used to drive reactions, e.g. growth of particles, materials or structures in proximity to the heated objects or feature. An electromagnetic excitation or light-matter interaction induced in a metallic particle could generate a thermal environment in particles, materials or structures in proximity to the excited particle and cause subsequent catalysis or growth, e.g. on a silicon wafer. This embodiment may further include cycling of temperatures in particles, materials or structures in proximity to the heated objects or features in the manner described by this invention. The method of controlling chemical reactions described in this invention may also permit significant and far-reaching applications in the use of existing deposition or fabrication techniques employed in a variety of industrial, chemical, manufacturing, engineering and conversion technologies.

In an alternative embodiment, this invention could provide for localized heating effects to be induced in non-metallic, organic or inorganic materials as the continuation of a plasmon assisted deposition, reaction or similar process. The method may employ the use of plasmon resonant frequency effects on a metallic catalyst to initiate and control a reaction in an adjacent non-catalyzed, non-metallic material. Continued plasmon resonant frequency oscillation of the catalyst may cause prolonged heating of the selected adjacent material. This would provide for the use of the selected electromagnetic excitation or light-matter interactions to generate controlled localized thermal conditions in organic or inorganic materials for a variety of purposes.

In an exemplary embodiment this invention may include exciting electromagnetic energy in a structure or material, which contains an addressable plasmon resonant frequency so as to influence one or more specific properties of said structure or material. In some implementations this provides a means to use electromagnetic excitation or light-matter interactions to influence, cause, control, modulate, stimulate or change the state or phase of electrical, magnetic, optical or electromagnetic charge, emission, conduction, storage or similar properties. The method could include the use of light-matter interactions to generate electromagnetic excitation and concentrate extremely localized field effects or concentrated plasmonic field effects to cause an exchange of energy states in a material or structure. Said field effects could be used for excitation of surface electrons in metallic nanostructures causing said electrons to exchange energy states or said field effects could be used to mediate or stimulate photon emissions or modulate photonic energy to excite or stimulate emissions of electrons.

An opportunity may exist to use the invention described herein to exploit solar or light energy more efficiently. The full spectrum of solar or light energy is very broad and many photons are not used efficiently by any known process. The loss mechanism in typical solar cell conversion efficiency is between 90% and 99%. Commercially available silicon based semiconductor dielectric materials have a power conversion efficiency rate of between approximately 5% and 10%. Because of their complex structure and precise engineering requirements, the wafers from which these photovoltaic solar cells are made are expensive to produce and consume significant energy in the fabrication process offsetting any economic or environmental benefits. The failure rate in fabrication is as high as 50%, which adds to the ecological disadvantages. Silicon materials are fragile in operation and deployment with limited lifetimes and diminishing performance. A new generation of photovoltaic solar cells, which are not yet widely available, have been proposed using organic polymer or plastic thin film combined with nanostructured inks or dyes. It has been claimed that these materials can be fabricated more easily and at a lower cost than silicon based devices. The demonstrated power conversion efficiency rate for this class of solar cells is between only 1% and 3%. These materials promise to be more robust than silicon, but would need to be deployed over massive areas. No thermal solar cells or materials have been developed or proposed that combine the use of photovoltaic and thermal engineering for more efficient conversion. All of the current and proposed photovoltaic and thermal solar cells or materials use toxic, inorganic or ecologically harmful materials and consume substantial fossil fuel or non-renewable energy supplies in fabrication and manufacture. The invention described herein combines photovoltaic, plasmonic and thermal engineering with a variety of non-toxic, organic, and ecologically stable elements more particularly described. Said invention provides improved power conversion efficiency and power generation with lower fabrication or energy costs and reduced environmental impact. Some or all of the methods or means described herein could enable the use of solar energy to fabricate or supply power for the fabrication of materials or devices described in this invention. Said materials or devices could be used for solar, thermal or other energy production in the manner described in this invention.

In an embodiment the invention described herein could provide a method to use thermal engineering for more efficient solar energy. Said use may include photovoltaic and thermal engineering in any combination in a solar cell or material. Said use may further include thermal, plasmonic, photovoltaic or thermophotovoltaic solar cells or materials in any combination. Strong light-matter interactions are found in metallic nanostructures. Metal nanostructures or nanopatterned metallic or nonmetallic structures have been shown to absorb light more precisely and efficiently than other materials.

In an exemplary embodiment, the invention described herein may be used for the generation of energy through the use of light-matter interactions driven by a laser, lamp, light or solar energy by use of some or all of the following steps:
1) Deploy metallic, organic or metalorganic nanostructures or nanoengineered materials as antennas or receivers for the capture of light energy from solar or other sources into or on to any coating or substrate.
2) Inscribe, write, print, etch, engrave, roughen, cavitate, pit or otherwise impress the surface or subsurface of any material or substrate in regular or random patterns, designs, gratings or waveguides to separate the light energy into discrete wavelengths or frequencies.
3) Use transparent nanopatterned metallic structures or films as dielectric waveguide materials to separate the light energy into discrete wavelengths or frequencies.
4) Enhance or concentrate field intensity through surface plasmon excitation using metallic nanostructures.
5) Enhance localized field effects to stimulate photon emission rates.
6) Control or focus enhanced photon emissions using a combination of factors or properties of metallic nanoparticles including absorption, morphology, size, positioning, composition or similar factors.
7) Combine transparent nanopatterned metallic structures or thin-films as contacts or electrodes to create organic photovoltaic subcells or multijunction stacks.
8) Spectrally or optically tune the organic photovoltaic subcells or multijunction stacks.
9) Enhance absorption properties through the conductivity of transparent metal contacts.
10) Use metallic nanoparticles to act as strong absorbers of light energy with a high thermal index realization.
11) Use selective absorption of ultraviolet light to act as a coating or filter in any organic material.
12) Select or combine metallic nanoparticles, which have a plasmon resonance that matches the frequency of ultraviolet light to act as an absorption coating or filter in any organic material.
13) Use the absorption properties of selected metallic nanoparticles to efficiently absorb ultraviolet light from solar or other sources and prevent degradation of organic materials.
14) Convert the ultraviolet light absorbed from solar or other light sources to heat by means of said absorption. Use, transport or store the heat so acquired for any purpose.
15) Acquire light energy across any portion of or the entire spectrum.
16) Convert acquired light energy into heat by absorption or reflection.
17) Use the plasmon resonant frequency of metallic nanostructured materials to separate the acquired light energy spectrum into discrete wavelengths.
18) Use the plasmon frequency for excitation of surface plasmons to enhance transmission of light energy to a desired area.
19) Use metallic nanoparticles for plasmon enhanced catalysis to convert light energy into heat or to start catalytic or chemical reactions.
20) Transfer generated heat to a gas, liquid, solid, plasma or any other material.
21) Combine gas, liquid, solid, plasma or any other material with or in proximity to heated nanoparticle surfaces.
22) Transfer heat to a reactor or chamber to drive a turbine, engine, sterling engine, alternator, converter, generator or any other device for the creation of electrical current or for any purpose.
23) Use heat derived from light energy to excite the molecular or kinetic properties of a gas, liquid, solid, plasma or any other material to drive a turbine, engine, sterling engine, alternator, converter, generator or any other device for the creation of electrical current or for any purpose.
24) Combine or incorporate any or all of the aforementioned materials into a coating, compound, composite, thin film or any other form factor.
25) Incorporate or integrate any or all of the coating, compound, composite, thin film or any other form factor materials containing the features described herein as an internal or external aspect or means to use light energy or heat to drive a turbine, engine, sterling engine, alternator, converter, generator or any other device or for any purpose.

This embodiment may use any or all of the aforementioned steps in combination with each other or alone. The steps may be used in this order or in any other order with omission or addition of any other steps.

In an exemplary embodiment, some of the steps listed in the previous embodiment may be used for or in conjunction with some or all of the following methods or steps:
1) The engineering of a tunable, addressable coating or black body structure to permit control of convection, conduction, concentration, absorption, radiation, emission, and scattering of radiation.
2) Said coating or black body structure could be applied to any substrate.
3) Such a coating or black body structure may have the ability to enhance the thermal properties of any substrate.
4) The substrate or part of the substrate may act as a heat sink.
5) Solar radiation absorbed by a black body may be transferred to the substrate or to a separate heat sink.
6) Heat may be transferred to a working fluid, gas, plasma or liquid and used to drive a turbine, generator, alternator or similar device or otherwise utilize thermal energy to create electrical energy.
7) The engineering of an evacuated transparent or opaque housing or structure.
8) The provision of a space in said structure filled by a vacuum or gas.
9) The placement or positioning on the interior or exterior of said structure of materials designed to act as filters, intermediate absorbers and selective emitters.

A method of enabling the various functions, tasks or features contained in this invention may include performing the operation of some or all of the following steps in conjunction with a reaction chamber or other device in which catalytic or synthetic chemical reactions could be controlled:

determine the frequency range for the electromagnetic excitation or light-matter interactions of the resonant frequency of a material.

determine the absorption of a unit of electromagnetic energy by a material or combination of materials.

determine the emission of a unit of electromagnetic energy by a material or combination of materials.

determine the refraction of a unit of electromagnetic energy by a material or combination of materials.

determine the scattering of a unit of electromagnetic energy by a material or combination of materials.

identify the resonant frequency of a material or combination of materials.

sequence the electromagnetic excitation or light-matter interactions of the resonant frequency of a material or combination of materials.

organize the electromagnetic excitation or light-matter interactions of the resonant frequency of a material or combination of materials.

program the electromagnetic excitation or light-matter interactions of the resonant frequency of a material or combination of materials in time.

program the electromagnetic excitation or light-matter interactions of the resonant frequency of a material or combination of materials in space.

program the delivered power density of the electromagnetic excitation or light-matter interactions of the resonant frequency of a material.

program the spot size of the beam of the electromagnetic excitation or light-matter interactions of the resonant frequency of a material.

program the polarization of the electromagnetic excitation or light-matter interactions of the resonant frequency of a material.

cycle the electromagnetic excitation or light-matter interactions of the resonant frequency of a material or combination of materials.

repeat the electromagnetic excitation or light-matter interactions of the resonant frequency of a material or combination of materials.

automate the electromagnetic excitation or light-matter interactions of the resonant frequency of a material or combination of materials.

program or perform in-situ or ex-situ spectroscopy on the reaction products, including Raman, absorption, transmission and reflection measurements, gas analysis, chromatography, and mass spectroscopy.

In an exemplary embodiment the invention and process described herein could be incorporated in a device, e.g. a reactor, at a length scale down to or below a single nanometer. Said device could be introduced or distributed in any material such as a gas, liquid, solid or plasma, e.g. water, fuel or paint and could be addressed or monitored by electromagnetic excitation or light-matter interactions from an external, internal or remote energy source.

In an alternative embodiment such a device could include an energy source triggered by predetermined or variable properties of the host material or environment, e.g. temperature so as to activate or cause electromagnetic excitation or light-matter interactions, energy exchange or thermal energy transfer.

The various features of the invention described herein could be expressed in the following or any other architectures or form factors:

A metallic

A nonmetallic

An organic

An inorganic

A metal organic

A silicon

A silica

A silicate

A ceramic

A composite

A polymer

An organic composite thin film

An organic composite coating

An inorganic composite thin film

An inorganic composite coating

An organic and inorganic composite thin film

An organic and inorganic composite coating

A thin film crystal lattice nanostructure

An active photonic matrix

A flexible multi-dimensional film, screen or membrane

A microprocessor

A MEMS or NEMS device

A microfluidic or nanofluidic chip

A single nanowire, nanotube or nanofiber

A bundle of nanowires, nanotubes or nanofibers

A cluster, array or lattice of nanowires, nanotubes or nanofibers

A single optical fiber

A bundle of optical fibers

A cluster, array or lattice of optical fibers

A cluster, array or lattice of nanoparticles

Designed or shaped single nanoparticles at varying length scales

Nanomolecular structures

Nanowires, dots, rods, particles, tubes, sphere, films or like materials in any combination

Nanoparticles suspended in various liquids or solutions

Nanoparticles in powder form

Nanoparticles in the form of pellets, liquid, gas, plasma or otherwise

Nanostructures, nanoreactors, microstructures, microreactors, macrostructures or other devices

Combinations of nanoparticles or nanostructures in any of the forms described or any other form

Nanopatterned materials

Nanopatterned nanomaterials

Nanopatterned micro materials

Micropatterned metallic materials

Microstructured metallic materials

Metallic micro cavity structures

Metal dielectric materials

Metal dielectric metal materials

Combination of dielectric metal materials or metal dielectric metal materials

A paint, coating, powder or film in any form containing any of the materials identified herein or any other materials in any combination

All or any of the materials or forms described herein may be designed, used or deployed on or in flexible, elastic, conformable structures. Said structures or surface areas may be expanded or enlarged by the use of advanced non-planar, non-linear geometric and spatial configurations.

It is well known that the performance efficiency, yield and fuel economy of an internal combustion engine or system may be improved by the introduction or mixture of pure hydrogen with gasoline, diesel or biomass fuels during the combustion cycle. Various methods, schemes and devices are commercially available to achieve hydrogen injection. Said methods, schemes and devices are primarily in the form of auxiliary, supplemental, after-market treatments. The most common means of producing hydrogen is by electrolysis, (i.e. passing an electrical current through a solution of water and chemical substances or additives). The electrical current is derived from the battery or alternator used to supply necessary electrical power to the internal combustion engine or system. At least one alternative hydrogen injection scheme using primary fuel as the source of hydrogen gas is the subject of ongoing research with no commercial product. This scheme requires high voltage electrical currents to form high-temperature plasma. In theory the plasma is used to reform conventional fuel and add hydrogen gas to the fuel-air mixture supplied to the engine for improved combustion properties. No pre-combustion heating or cold start emission benefits are provided by these methods. A significant power load or draw on the electrical supply is required for all such devices. The ability to pre-heat the engine, the exhaust or the catalytic converter is not addressed by any of these systems. No sequestration or recovery of carbon materials is suggested by any such schemes.

In an exemplary embodiment the invention described herein may be used in a method or process of chemical catalysis with gasoline, diesel or biofuels to cause methane reformation, gas separation, hydrogen production and combustion. Said process may yield byproducts of Carbon (C), Oxygen (O) and Hydrogen (H), heat and water (H₂O). The method or process described by this invention may be incorporated in nano or microscale reactors or devices. Said devices may be used in conjunction with internal combustion engines. Operation of said devices may include some or all of the following steps:

Add or introduce metallic nanocatalysts, nanostructures, nanoparticles reactors or devices to the fuel supply,

Draw gasoline, diesel or other fuel in gas or vaporized form into a pre-combustion chamber,

Flow gas or vapor over or combine gas or vapor with metallic nanoparticles, nanostructures or nanocatalysts,

Direct a focused light source, e.g. a laser, lamp, light or solar energy at or in a predetermined wavelength or frequency to excite a corresponding plasmon resonant frequency in said catalysts,

Cause said catalytic, chemical, electrical, optical or thermal reaction to synthesize or reform gas or vapor into methane,

Flow methane gas over or combine methane gas with metallic nanoparticles, nanostructures or nanocatalysts,

Direct a focused light source, e.g. a laser, lamp, light or solar energy at or in a predetermined wavelength or frequency to excite a corresponding plasmon resonant frequency in said catalysts,

Cause said catalytic, chemical, electrical, optical or thermal reaction to convert methane (CH₄) into Carbon (C), Oxygen (O) and Hydrogen (H),

Sequester or recover Carbon (C),

Store or expel remaining pure water (H₂O),

Direct a focused light source, e.g. a laser, lamp, light or solar energy at or in a predetermined wavelength or frequency to excite a corresponding plasmon resonant frequency in said catalysts,

Cause said catalytic, chemical, electrical, optical or thermal reaction to ignite Hydrogen (H) and Oxygen (O) to produce heat,

Introduce heat into engine manifold, air intake or combustion chamber,

All of the aforementioned reactions may be derived from or may include light-matter interactions.

In a further exemplary embodiment the invention described herein may be used for a method or process of chemical catalysis to cause gas separation and hydrogen production in the post-combustion treatment of exhaust gases. Said process may yield byproducts of Carbon (C), Oxygen (O) and Hydrogen (H), heat and water (H₂O). The method or process described by this invention may be incorporated in nano or microscale reactors or devices. Said devices may be used in conjunction with internal combustion engines. Operation of said devices may include some or all of the following steps:

Draw exhaust gases into a post-combustion chamber in gas or vaporized form,

Flow exhaust gases over or combine exhaust gases with metallic nanoparticles, nanostructures or nanocatalysts,

Direct a focused light source, e.g. a laser, lamp, light or solar energy at or in a predetermined wavelength or frequency to excite a corresponding plasmon resonant frequency in said catalysts,

Cause said catalytic, chemical, electrical, optical or thermal reaction to convert or separate exhaust gases into Carbon (C), Oxygen (O) and Hydrogen (H),

Sequester or recover Carbon (C),

Store or expel remaining pure water (H₂O),

Direct a focused light source, e.g. a laser, lamp, light or solar energy at or in a predetermined wavelength or frequency to excite a corresponding plasmon resonant frequency in said catalysts,

Cause said catalytic, chemical, electrical, optical or thermal reaction to ignite Hydrogen (H) and Oxygen (O) to produce heat using,

Transfer heat to catalytic converter or exhaust engine manifold,

All of the aforementioned reactions may be derived from or may include light-matter interactions.

Said devices may be positioned in a variety of locations in any combustion engine or system. For pre-combustion the device may be located between any of the fuel supply or pump, the engine manifold, air intake and combustion chamber. For post-combustion the device may be located between any of the engine or exhaust manifold and catalytic converter. Said devices may be used with existing or advanced fuels in conventional and hybrid vehicles to reduce NOx emissions including CO₂. Conventional catalytic converters only achieve maximum efficiency above 250° C. As a result cold starts in combustion or hybrid combustion engines create high levels of NOx, CO₂ and other emissions. Hydrogen combustion may be used in the manner described or any similar fashion to overcome cold starts. Said devices may be used with any fuel in any combustion engine or system. Said devices offer improved fuel efficiency and reduced emissions including CO₂.

When deployed in any or any similar embodiment unique properties and benefits of the invention described herein may include:

Use of primary onboard fuel as the source of hydrogen

Instantaneous onboard hydrogen production and combustion

Safe onboard hydrogen reformation and combustion

The ability to overcome cold start emissions

Carbon sequestration and recovery

Use of solar or low-power laser energy

Operation at ambient temperatures and low pressure

Low-load or no-load on the electrical battery or supply system

### DESCRIPTION OF THE INVENTION

Metals can be thought of as a gas of conduction electrons. Similar to sound waves in a real gas, metals exhibit plasmon phenomena, i.e. electron density waves. Electron density waves can be excited at the interface between a metal and a dielectric. There is also a strong interaction of light with a metallic nanoparticle. At the surface plasmon resonance frequency, the electric field of a light wave induces a collective electron oscillation in the particle. Due to inelastic scattering processes, the kinetic energy of the electrons is rapidly converted to heat and the temperature of the nanoparticle is raised.

The time-varying electric field associated with light waves can exert a force on the gas of negatively charged electrons and drive them into a collective oscillation. There are interesting analogies of this phenomenon to driving a gas of molecules into a resonant collective oscillation by blowing on a flute. The motion of the oscillating electrons in the particles is strongly damped in collisions with other electrons and lattice vibrations (phonons) and the kinetic energy of the electrons is rapidly converted into heat on a 1-10 femtosecond timescale (one femtosecond=one quadrillionth of a second).

This process can be used for the rapid, controlled heating and cooling of particles to enable new methods for micro, nano manufacturing and molecular synthesis. It is important to note that very low energy input is required to obtain a significant temperature rise in nanoscale particles. This energy could be delivered in a spatially and temporally controlled fashion by solar energy, a lamp, a laser or a broadband solid-state light source. When the light source is interrupted the particle cools and the thermal energy gained rapidly dissipates into a larger, cooler thermal mass on which the particle is positioned (10 ps-1 ns). This process can be used for very fast switching between low and high temperature states of the particle.

In an alternative embodiment, this invention could provide for localized heating effects to be induced in non-metallic, organic or inorganic materials as the continuation of a plasmon assisted deposition, reaction or similar process. The method may employ the use of plasmon resonant frequency effects on a metallic catalyst to initiate and control a reaction in an adjacent non-catalyzed, non-metallic material. Continued plasmon resonant frequency oscillation on the catalyst may cause prolonged heating of the selected material. This would provide for the use of the selected electromagnetic excitation or light-matter interactions to generate controlled localized thermal conditions in organic or inorganic materials for a variety of purposes.

This invention further concerns the use of resonant light-matter interaction effects to attain controlled localized thermal conditions. In one implementation this invention could provide a means to deliver at least one form of electromagnetic energy to cause at least the combination, separation, reformation or reclamation of at least a gas, a combination of gasses, a material or a combination of materials in the form of a gas, plasma, solid or liquid. In an alternative implementation this invention could provide a means to initiate and control for the generation, use, transfer and output of controlled localized thermal energy.

The method of use disclosed could provide a means to realize local thermal conditions at the nanoscale below the diffraction limit for the electromagnetic waves used. In some implementations surface plasmon excitations may be used to achieve desired thermal conditions at the nanoscale. Nanoscale objects or apertures at the nanoscale allow electromagnetic energy to be addressed, concentrated or restricted to critical dimensions that are below the diffraction limit of the wavelength of irradiation used. These concentrated fields can be used by means of absorption to efficiently heat volumes of material down to or below the scale of a single nanometer. Due to the small heat capacity that volume of material would cool rapidly when the electromagnetic excitation or light-matter interactions is terminated. Depending on the thermal environment of the heated volume cooling could take place on a timescale down to or below a single picosecond. The concentration could lead to massive field enhancements resulting in extreme control of light-matter interactions and local heating.

The method of use could further provide for surface plasmon resonance effects or light-matter interactions to take place in a thermally controlled environment, particle, material or structure. In some circumstances the method may include changing, reducing or controlling the temperature of said environment, particle, material or structure in order to achieve greater efficiency in realizing any of the effects obtained by the invention described herein.

In an exemplary embodiment of the invention described herein the selective excitation of electrons, molecules, particles, materials and structures can be controlled by means of a surface plasmon resonant frequency excited by the use of electromagnetic radiation or energy transfer.

In any exemplary embodiment or description contained herein the method of enabling the various functions, tasks or features contained in this invention includes performing the operation of some or all of the steps outlined in conjunction with the preferred processes or devices. This description of the operation and steps performed is not intended to be exhaustive or complete or to exclude the performance or operation of any additional steps or the performance or operation of any such steps or the steps in any different sequence or order.

The foregoing means and methods are described as exemplary embodiments of the invention. Those examples are intended to demonstrate that any of the aforementioned steps, processes or devices may be used alone or in conjunction with any other in the sequence described or in any other sequence.

What is claimed is:

1. A method to excite at least one form of electromagnetic excitation or light-matter interaction in a structure, which incorporates at least one material including:
A means which incorporates at least one material which contains at least an addressable frequency in at least a material or combination of materials including at least a metallic, nonmetallic, organic, inorganic, metal organic, silicon, silica, silicate, ceramic, composite or polymer.
A means which incorporates at least one dielectric material which contains at least an addressable frequency to cause at least an electrical charge.
A means which incorporates at least one conductive material which contains at least an addressable frequency to cause at least an electrical charge.
A means which incorporates at least one thermoelectric material which contains at least an addressable frequency to cause at least an electrical charge.
A means which incorporates at least one thermionic material which contains at least an addressable frequency to cause at least an electrical charge.
A means which incorporates at least one material which can be caused to change its shape or dimensions by expansion or contraction and which contains at least an addressable frequency.
A means which incorporates at least one material which can be made to store at least a unit of information in at least the form of at least a positive magnetic charge.
A means which incorporates at least one material which can be made to store at least a unit of information in at least the form of at least a negative magnetic charge.
A means which incorporates at least one material which can be made to change phase and, which contains at least an addressable frequency.
A means which incorporates at least one material which can be separately addressed and which contain at least an addressable frequency which can be made to cause the emission of at least an electron.
A means which incorporates at least a material which can be separately addressed and which contain at least an addressable frequency which can be made to cause the emission of at least a photon.
A means which incorporates at least a material which can be separately addressed and which contain at least an addressable frequency which can be made to cause the emission of at least a phonon.
A means which incorporates at least a material which can be separately addressed and which contain at least an addressable frequency which can be made to perform the function of at least a capacitor.
A means which incorporates at least a material which can be separately addressed and which contain at least an addressable frequency which can be made to perform the function of at least a resistor.
A means which incorporates at least a material which can be separately addressed and which contain at least an addressable frequency which can be made to perform the function of at least a transistor.
A means which incorporates at least a material which can be separately addressed and which contain at least an addressable frequency, which can be made to perform the function of at least a semiconductor
A means which incorporates at least two materials which can be separately addressed and which contains at least an addressable frequency.
A means which incorporates at least two materials which can be separately addressed and which contain at least an addressable frequency which can be made to cause at least one metallic particle to emit a positive electrical charge.
A means which incorporates at least two materials which can be separately addressed and which contain at least an addressable frequency which can be made to cause at least one metallic particle to emit a negative electrical charge.
A means which incorporates at least two materials which can be separately addressed and which contain at least an addressable frequency which can be made to cause at least one metallic particle to occupy a positive electrically charged state.
A means which incorporates at least two materials which can be separately addressed and which contain at least an addressable frequency which can be made to cause at least one metallic particle to occupy a negative electrically charged state.
A means which incorporates at least two materials which can be separately addressed and which contain at least an addressable frequency which can be made to cause at least one metallic particle to switch between the positive and negative charged states.
A means which incorporates at least two materials which can be separately addressed and which contain at least an addressable frequency which can be made to cause the emission of at least an electron.
A means which incorporates at least two materials which can be separately addressed and which contain at least an addressable frequency which can be made to cause the emission of at least a photon.
A means which incorporates at least two materials which can be separately addressed and which contain at least an addressable frequency which can be made to cause the emission of at least a phonon.
A means which incorporates at least two materials which can be separately addressed and which contain at least an addressable frequency which can be made to perform the function of at least a capacitor.
A means which incorporates at least two materials which can be separately addressed and which contain at least an addressable frequency which can be made to perform the function of at least a resistor.
A means which incorporates at least two materials which can be separately addressed and which contain at least an addressable frequency which can be made to perform the function of at least a transistor.
A means which incorporates at least two materials which can be separately addressed and which contain at least an addressable frequency which can be made to perform the function of at least a semiconductor.
A means which incorporates at least a material which can be separately addressed and which contain at least an addressable frequency which can be made to perform the function of at least memory storage.
A means which incorporates at least a material which can be separately addressed and which contain at least an addressable frequency which can be made to perform the function of restoring at least a unit of information as at least a signal for universal computing.
A means which incorporates at least a material which can be separately addressed and which contain at least an addressable frequency which can be made to perform the function of inverting at least a unit of information as at least a signal for universal computing.
A means which incorporates at least two materials which can be separately addressed and which contain at least an addressable frequency which can be made to perform the function of restoring at least a unit of information as at least a signal for universal computing.
A means which incorporates at least two materials which can be separately addressed and which contain at least an addressable frequency which can be made to perform the function of inverting at least a unit of information as at least a signal for universal computing.

2. The method of claim 1 to excite at least one form of electromagnetic excitation or light-matter interactions in a structure, which incorporates at least one or two materials which can be separately addressed and which contain at least an addressable frequency or structure including:
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to cause or control the movement of at least a component which can direct or redirect at least a unit of electromagnetic, electronic or photonic energy.
A means which incorporates at least one material which contains at least an addressable frequency in at least a flexible, conformable, addressable structure which may be expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a flexible, conformable, addressable structure which may be expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures which structures may contain at least nanowires, dots, rods, particles, tubes, sphere, films or like materials in any combination.
A means which incorporates at least one material which contains at least an addressable frequency in at least a planar one dimensional flexible, conformable, addressable structure which may be expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a two dimensional flexible, conformable, addressable structure which may be expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a multi-dimensional flexible, conformable, addressable structure which may be expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency which can at least be a variable frequency in at least a flexible, conformable, addressable structure which may be combined with at least one like structure expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a flexible, conformable, addressable structure which may be expressed as a template in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a flexible, conformable, addressable structure at least portions of which may be instructed to output thermal energy expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency at least portions of which may be instructed to respond to thermal energy expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least one material which contains at least an addressable frequency in at least a flexible, conformable, addressable structure at least portions of which may be instructed to cause the transfer of precise localized thermal energy, expressed in at least a matrix, film, lattice, mesh, membrane, screen, mask, micro electrical mechanical systems device, nanoelectrical mechanical systems device, microchemical systems, microprocessor, semiconductor, crystalline lattice, microfluidics or nanofluidics channel, or a plurality, multiplicity, series or combination of any such forms or structures or any such or similar forms or structures.
A means which incorporates at least two materials which can be separately addressed and which contain at least an addressable frequency which can be made to perform the function of at least memory storage.
A means which incorporates at least one material which contains at least an addressable frequency in at least a gas, liquid, solid, plasma or any other material or solid form, which can be heated to at least a specified temperature.
A means which incorporates at least one material which contains at least an addressable frequency in at least a gas, liquid, solid, plasma or any other material or solid form, which can be heated to at least a specified temperature in at least a channel to provide at least sufficient kinetic energy to drive at least a turbine to generate electricity or cause an electrical current.
A means which incorporates at least one material which contains at least an addressable frequency in at least a gas, liquid, solid, plasma or any other material or solid form, which can be heated to at least a specified temperature in at least a channel to provide at least sufficient kinetic energy to drive at least an engine or at least a device to generate electricity or cause an electrical current.
A which incorporates at least one material which contains at least an addressable frequency in at least a gas, liquid, solid, plasma or any other material or solid which can be heated to at least a specified temperature to provide at least sufficient energy to cause at least one material to expand or contract.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to open or close a contact connection or circuit.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to exchange or store at least a unit of energy or at least a unit of information.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to direct at least a unit of electromagnetic, electronic or photonic energy.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to cause at least one material to switch between a positive and negative energy state.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to redirect at least a unit of electromagnetic, electronic or photonic energy.
A means which incorporates at least one material which contains at least an addressable frequency in at least a gas, liquid, solid, plasma or any other material or solid confined in at least a channel or similar structure which can be heated to at least a specified temperature to provide at least sufficient energy to cause at least one material to expand or contract so as to cause or control the movement of at least a component which can direct or redirect at least a unit of electromagnetic, electronic or photonic energy.

3. A method to use light-matter interactions to at least concentrate electromagnetic energy to at least excite surface electrons including:
A means in which at least light matter interactions are used to at least concentrate electromagnetic energy to at least excite surface electrons in at least metallic nanostructures.
A means in which light-matter interactions are used to at least excite at least surface electrons in at least metallic nanostructures to at least cause an exchange of energy states.
A means in which light-matter interactions are used to at least excite at least surface electrons in at least metallic nanostructures to at least cause electrons to exchange energy states and at least stimulate the emission of at least a photon.
A means in which light-matter interactions are used to at least excite at least surface electrons in at least metallic nanostructures to at least stimulate photon emissions.
A means in which light-matter interactions are used to at least excite at least surface electrons in at least metallic nanostructures to at least stimulate and at least use photon emissions in photochemical, photocatalysis, photovoltaic or thermophotovoltaic reactions.

4. A method to excite at least one form of electromagnetic excitation or light-matter interaction to generate electromagnetic excitation and concentrate extremely localized field effects or concentrated plasmonic field effects including:
A means to cause an exchange of energy states in a material or structure.
A means to use at least extremely localized or concentrated plasmonic field effects for the excitation of surface electrons in metallic nanostructures or nanoengineered materials to cause electrons to exchange energy states.
A means to use at least the exchange of energy states in excited electrons to mediate or stimulate photon emissions or modulate photonic energy to excite or stimulate emissions of electrons.
A means to use at least electron or photon emissions to drive photochemical, photocatalysis, photovoltaic or thermophotovoltaic reactions.
A means to use at least the exchange of energy states to perform the functions of at least a solar cell.
